(19) United States
(12) Patent Application Publication
(10) Pub. No.: US 2021/0263415 A1
(43) Pub. Date: Aug. 26, 2021

(54) DISPLAY PANEL AND NEGATIVE PHOTORESIST MATERIAL

(71) Applicant: TCL China Star Optoelectronics Technology Co.,LTD, Shenzhen, Guandong (CN)

(72) Inventor: Xue LIU, Shenzhen, Guangdong (CN)

(21) Appl. No.: 16/757,404

(22) PCT Filed: Mar. 23, 2020
(86) PCT No.: PCT/CN2020/080666

§ 371 Date: Apr. 19, 2020

(30) Foreign Application Priority Data
Feb. 24, 2020 (CN) 202010113025.8

(51) Int. Cl. G03F 7/075; C08F 290/14

(52) U.S. Cl. CPC G03F 7/0757; G02F 1/133516; C08F 290/148

(57) ABSTRACT

The present application provides a display panel and a negative photoresist material. The display panel of the present application includes a photoresist layer, the photoresist layer includes a negative photoresist material, the negative photoresist material includes an acrylate polymer with cage polysilsesquioxanec, The acrylate polymer with cage polysilsesquioxanec is used to improve a thermal performance of the negative photoresist material.

### CROSS REFERENCE TO RELATED APPLICATION

This application claims priority to Chinese Application No. 202010113025.8, filed on 2020 Feb. 24, titled “Display Panel and Negative Photoresist Material”. The entire disclosure of the above application is incorporated herein by reference.

### BACKGROUND OF INVENTION

### Field of Invention

The present application relates to the field of display, and particularly to a display panel and a negative photoresist material.

### Description of Prior Art

Color filter substrates (CF substrates) of thin film transistor-liquid crystal displays (TFT-LCDs) are made by processes including black matrix (BM)/red (R)/green (G)/blue (B)/photoresist (PS)/indium tin oxide (ITO). During a manufacturing process for manufacturing a color filter (CF) substrate, lithography technology is employed in every process of conventional technology. A manufacturing method is as followed: first, a negative photoresist is coated to form a film, which is employed by an exposure process with a mask, an exposure portion is cured and can not react with a developing liquid, which is retained after a developing process; and finally, a pattern is obtained by a baking process.

During the entire manufacturing process for manufacturing the CF substrate, a plurality of baking processes are employed. Now, the main component of the negative photoresist polymer is acrylate polymer, a backbone of which is acrylate skeleton, which lacks rigid structure, has a slightly worse thermal properties, and creates process risk, for example, small molecule outgas and baked sublimate generated after several baking processes are easy to contaminate the baking machine, increase machine maintenance times, and take up a lot of capacity, which can also affects a film forming characteristics of the post-process. In addition, high temperature processes such as a frame glue curing process, a heating partial fit process, and so on are employed after the thin film transistor substrate (TFT substrate) and the CF substrate combined with each other, a thermal performance of the photoresist can also affect the product performance, for example, photoresist material with a poor thermal performance at a box formation has an outgas risk during the high temperature process, which will cause product bubbles. Therefore, it is necessary to improve the thermal performance of negative photoresist materials.

### SUMMARY OF INVENTION

The present application provides a display panel and a negative photoresist material to solve a problem of a negative photoresist with a poor thermal performance being easy to generate baked sublimate, generate small molecule outgas, and affect a product performance.

The present application provides a display panel, a photoresist layer of the display panel includes a negative photoresist material, the negative photoresist material comprises an acrylate polymer with cage polysilsesquioxanec, functional groups connected to Si atoms located at eight corners of a cage structure of the cage polysilsesquioxanec are vinyl groups, and the vinyl groups are connected to a skeleton of the acrylate polymer.

In some embodiments, the cage polysilsesquioxanec is obtained by vinyl alkoxysilane reacted by a hydrolysis and condensation reaction under an action of an acid catalyst.

In some embodiments, the vinyl alkoxysilane is vinyl trimethoxy silane.

In some embodiments, via a polymerization reaction, the vinyl groups of the cage polysilsesquioxanec are connected to a skeleton of the acrylate polymerskeleton.

In some embodiments, the polymerization reaction is a free radical polymerization.

In some embodiments, the polymerization reaction is an emulsion polymerization.

In some embodiments, the acrylate polymer is one or a group selected from methacrylate, ethyl acrylate, epoxy acrylate, and pure acrylate.

The present application also provides a display panel, a photoresist layer of the display panel includes a negative photoresist material, the negative photoresist material comprises an acrylate polymer with cage polysilsesquioxanec.

In some embodiments, functional groups connected to Si atoms located at eight corners of a cage structure of the cage polysilsesquioxanec are vinyl groups.

The present application also provides a negative photoresist material, the negative photoresist material comprises an acrylate polymer with cage polysilsesquioxanec.

In some embodiments, functional groups connected to Si atoms located at eight corners of a cage structure of the cage polysilsesquioxanec are vinyl groups.

In some embodiments, the vinyl groups of the cage polysilsesquioxanec are connected to a skeleton of the acrylate polymerskeleton.

In some embodiments, the cage polysilsesquioxanec is obtained by vinyl alkoxysilane reacted by a hydrolysis and condensation reaction under an action of an acid catalyst.

In some embodiments, the vinyl alkoxysilane is vinyl trichloro silane.

In some embodiments, the vinyl alkoxysilane is vinyl trichloro silane.

In some embodiments, via a polymerization reaction, the vinyl groups of the cage polysilsesquioxanec are connected to the acrylate polymerskeleton.

In some embodiments, the polymerization reaction is a free radical polymerization.

In some embodiments, the polymerization reaction is an emulsion polymerization.

In some embodiments, the acrylate polymer is one or a group selected from methacrylate, ethyl acrylate, epoxy acrylate, and pure acrylate.

The benefit of the present application is: the present application provides a display panel, a negative photoresist material of a photoresist layer of the display panel comprises an acrylate polymer with cage polysilsesquioxanec. For the display panel, a thermal performance of the negative photoresist material of the photoresist layer can affect the product performance of the display panel; parameters of the thermal performance include a heat resistance and a thermal stability. The idea of this application is: the cage polysilsesquioxanec structure is added to the acrylate polymer of the negative photoresist material, the cage skeleton has a stronger rigidity and a larger molecular weight, this rigid structure with a macromolecular chain is benefit to increase a heat resistance of the negative photoresist material; the larger molecular weight of the polymer can improve a thermal stability of the negative photoresist material. Therefore, risk occurred by differences of the thermal performances is reduced in a manufacturing process of the display panel, the product performances of the display panel affected by bubbles generated in the products is avoided.

In one embodiment, vinyl groups are located at eight corners of a cage structure of the cage polysilsesquioxanec, the vinyl groups are reacted with the acrylic ester skeleton to make the cage polysilsesquioxanec cross link to the acrylate polymer, thereby obtaining a modified hybrid polymer. Because the cross linked vinyl groups can limit molecular chain to move, the heat resistance and the thermal stability of the negative photoresist material is furtherly improved.

The present application provides a negative photoresist polymer, the negative photoresist polymer is a acrylate polymer with cage polysilsesquioxanec, because the cage polysilsesquioxanec is added, the cage skeleton has a stronger rigidity and a larger molecular weight, this rigid structure with a macromolecular chain is benefit to increase a heat resistance of the negative photoresist material; the larger molecular weight of the polymer can improve a thermal stability of the negative photoresist material.

### BRIEF DESCRIPTION OF DRAWINGS

FIG. 1 is a flow diagram of a manufacturing method of a photoresist layer of a display panel of one embodiment according to the present application.

FIG. 2 is a flow diagram of a manufacturing method of a negative photoresist material of one embodiment according to the present application.

### DETAILED DESCRIPTION OF PREFERRED EMBODIMENTS

The technical solutions in the embodiments of the present application will be clearly and completely described with reference to the accompanying drawings in the embodiments of the present application. Obviously, the described embodiments are only a part of the embodiments of the present application, but not all of the implementation example. Based on the embodiments in the present application, all other embodiments obtained by those skilled in the art without creative work fall into the protection scope of the present application.

In the description of this application, it should be understood: the terms “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, etc. of directions or positional relationships are based on the directions or positional relationships of the drawings, The directions or position relationships shown is only for the convenience of describing this application and simplifying the description, and does not indicate or imply that the device or element referred to have a specific orientation, structure and operation in a specific orientation, so it cannot be understood as limit. In addition, the terms “first” and “second” are used for descriptive purposes only, and should not be interpreted as indicating or implying relative importance or implicitly indicating the number of technical features indicated. Thus, “first”, “second” features may explicitly or implicitly include one or more of the features. In the description of this application, the meaning of “multiple” is two or more, unless specifically defined otherwise.

The present application provides a display pane and a negative photoresist material, which are described in detail below.

Parameters of the thermal performance include a heat resistance and a thermal stability, the heat resistance can be improved by increasing the rigid structure of the molecular chain, such as reducing the single bond structure in the polymer chain, and adding conjugated double, triple and cyclic structures; improving the polymer crystallization can also improve the thermal performance of the polymer, for example, the melting temperature (240° C.) of isotactic polystyrene is much higher than the glass transition temperature (80° C.) of atactic polystyrene; in addition, chemical bonds between polymer bonds can hinder the chain movement after cross-linking, which can improve the heat resistance. The thermal stability of material has a relationship with bond energy constituting polymer chemical bonds, increasing polymer molecular weight and increasing a bond energy of the chemical bonds can make material more stable, for example, avoiding weak bonds in the polymer chain, introducing a large proportion of cyclic structures, and synthesizing trapezoidal and spiral-shaped polymers can improve the thermal stability of the polymer.

Cage polysilsesquioxanec (POSS) is a cage structure, composed of an inorganic core composed of silicon-oxygen skeletons alternately connected by Si—O and a functional group R group connected by Si atoms at its eight apex angles. R group can be a reactive or inert group. POSS is commonly used in polymer modification to form organic-inorganic hybrid polymers, which can effectively improve the thermal properties of polymers. Therefore, the embodiment of this application uses octavinyl-POSS modified acrylate polymer to improve the thermal performance of the negative photoresist material.

First, the present application provides a display panel, a photoresist layer of the display panel n photoresist layer includes a negative photoresist material, the negative photoresist material comprises an acrylate polymer with cage polysilsesquioxanec.

Specifically, functional groups connected to Si atoms located at eight corners of a cage structure of the cage polysilsesquioxanec are vinyl groups.

It should be noted that the above display panel embodiment only describes the above structure. It can be understood that, in addition to the above structure, the display panel in this embodiment of the present application may also include any other necessary structures, such as a substrate, a liquid crystal material, and a TFT substrate, etc., is not limited here.

The present application provides a display panel, a negative photoresist material of a photoresist layer of the display panel comprises an acrylate polymer with cage polysilsesquioxanec. For the display panel, a thermal performance of the negative photoresist material of the photoresist layer can affect the product performance of the display panel; parameters of the thermal performance include a heat resistance and a thermal stability. The idea of this application is the cage polysilsesquioxanec structure is added to the acrylate polymer of the negative photoresist material, the cage skeleton has a stronger rigidity and a larger molecular weight, this rigid structure with a macromolecular chain is benefit to increase a heat resistance of the negative photoresist material; the larger molecular weight of the polymer can improve a thermal stability of the negative photoresist material. Therefore, risk occurred by differences of the thermal performances is reduced in a manufacturing process of the display panel, the product performances of the display panel affected by bubbles generated in the products is avoided.

Vinyl groups are located at eight corners of a cage structure of the cage polysilsesquioxanec, the vinyl groups are reacted with the acrylic ester skeleton to make the cage polysilsesquioxanec cross link to the acrylate polymer, thereby obtaining a modified hybrid polymer. Because the cross linked vinyl groups can limit molecular chain to move, the heat resistance and the thermal stability of the negative photoresist material is furtherly improved, and the thermal performance of the negative photoresist material is improved.

On the basis of the above embodiments, the present application also provides a manufacturing method of a display panel.

The method includes:

A black matrix is coated on a substrate;

The negative photoresist material with acrylate polymer with cage polysilsesquioxanec is coated on the black matrix to form a photoresist layer.

In the embodiment, functional groups connected to Si atoms located at eight corners of a cage structure of the cage polysilsesquioxanec are vinyl groups;

The photoresist layer is employed by exposing, developing, and baking to form a CF substrate.

A frame glue is coated on the CF substrate to make it adhere to a TFT substrate, liquid crystal is injected between the CF substrate and the TFT substrate, thereby obtaining a display panel.

On the basis of the above embodiments, the present application also provides a manufacturing method of a photoresist layer of a display panel.

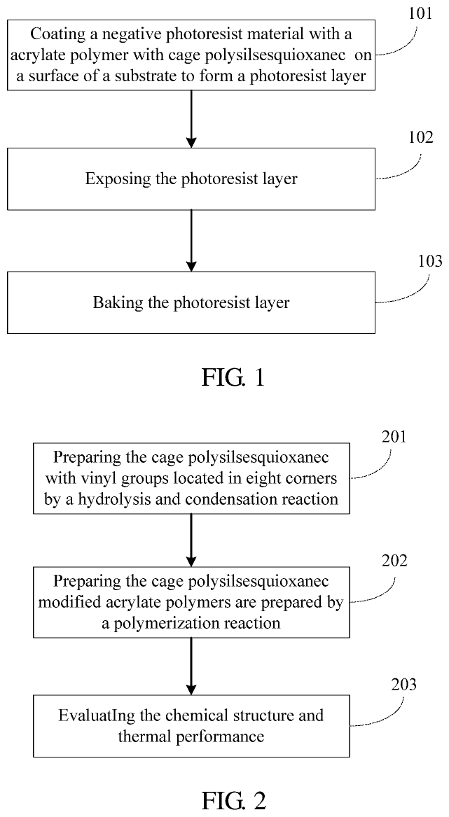

Referring to FIG. 1, FIG. 1 is a flow diagram of a manufacturing method 1 of a photoresist layer of a display panel of the present application. The method includes:

101, A negative photoresist material with the acrylate polymer with cage polysilsesquioxanec is coated on a surface of a substrate to form a photoresist layer;

102, The photoresist layer is exposed; and

103, The photoresist layer is baked.

Specifically, functional groups connected to Si atoms located at eight corners of a cage structure of the cage polysilsesquioxanec are vinyl groups.

The present application provides the manufacturing method of the display panel, the acrylate polymer with cage polysilsesquioxanec is used as a photoresist layer. The display panel produced by this method has a simple manufacturing process, and can avoid the occurrence of small molecule outgas sing after multiple baking, or the formation of baking sublimates, which can pollute the baking machine; reduce the number of machine maintenance and reduce consumption production capacity; avoid affecting film-forming characteristics in subsequent processes, and provide a new idea for the display panel preparation method.

In another embodiment of the present application, a negative photoresist material is provided. The negative photoresist material comprises an acrylate polymer with cage polysilsesquioxanec.

Specifically, functional groups connected to Si atoms located at eight corners of a cage structure of the cage polysilsesquioxanec are vinyl groups.

Specifically, the vinyl groups of cage polysilsesquioxanec are connected to the acrylate polymer.

It should be noted that the above structure is only described in the foregoing negative photoresist material embodiment. It can be understood that, in addition to the above structure, the negative photoresist material in the embodiment of the present application may also include any other necessary ingredients, such as solvents and sensitizers, are not specifically limited here.

The present application provides a negative photoresist polymer, the negative photoresist polymer is a acrylate polymer with cage polysilsesquioxanec, because the cage polysilsesquioxanec is added, the cage skeleton has a stronger rigidity and a larger molecular weight, this rigid structure with a macromolecular chain is benefit to increase a heat resistance of the negative photoresist material; the larger molecular weight of the polymer can improve a thermal stability of the negative photoresist material. A new idea is provided for the preparation of negative photoresist polymers to improve thermal stability.

On the basis of the above embodiments, the present application also provides a manufacturing method of a negative photoresist material.

Referring to FIG. 2, FIG. 2 is a flow diagram of a manufacturing method of a negative photoresist material of the present application. The method includes:

201, The cage polysilsesquioxanec with vinyl groups located in eight corners is prepared by a hydrolysis and condensation reaction. The specific reaction formula is:

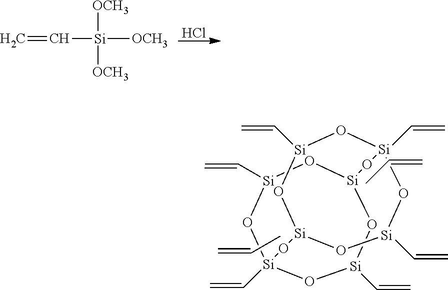

202, Cage polysilsesquioxanec modified acrylate polymers are prepared by a polymerization reaction or a cross-linking reaction to obtain a negative photoresist material containing cage polysilsesquioxanec modified acrylate polymer.

203, The structure of the modified negative photoresist material was confirmed by Fourier Transform Infrared Spectrometer (FTIR), Nuclear Magnetic Resonance Spectroscopy, Flight Mass Spectrometry, and Gel Permeation Chromatography (GPC) analysis, and the thermal performance can be evaluated by thermogravimetric analysis and Differential analysis Scanning calorimetry (DSC) analysis.

Specifically, the cage polysilsesquioxanec is obtained by vinyl alkoxysilane reacted by a hydrolysis and condensation reaction under an action of an acid catalyst.

Specifically, vinyl alkoxysilane is vinyl trimethoxy silane or vinyl trichloro silane.

Specifically, the polymerization reaction is a free radical polymerization or an emulsion polymerization.

Specifically, the acrylate polymer can be one or a group selected from methacrylate, ethyl acrylate, epoxy acrylate, and pure acrylate, also can be a polymer commonly used in other photoresist materials.

A manufacturing method of a negative photoresist polymer is provided in the embodiments of the present application. By this method, a cage polysilsesquioxanec is modified to an acrylate polymer, and a new type of negative photoresist can be prepared, thereby solving a problem of a negative photoresist with a poor thermal performance being easy to generate baked sublimate, generate small molecule outgas, and affect a product performance.

The display panel and the preparation method thereof, negative photoresist material and the preparation method thereof provided in the embodiments of the present application have been described in detail above. Specific examples have been applied herein to explain the principle and implementation of the present application. The descriptions of the above embodiments are only used to help understand the method of the present application and its core ideas; at the same time, for those skilled in the art, according to the ideas of this application, there will be changes in the specific implementation and application scope. On the above, the content of this specification should not be understood as a limitation on this application.

What is claimed is:

1. A display panel, wherein a photoresist layer of the display panel comprises a negative photoresist material, the negative photoresist material comprises an acrylate polymer with cage polysilsesquioxanec, functional groups connected to Si atoms located at eight corners of a cage structure of the cage polysilsesquioxanec are vinyl groups, and the vinyl groups are connected to a skeleton of the acrylate polymer.

2. The display panel of claim 1, wherein the cage polysilsesquioxanec is obtained by vinyl alkoxysilane reacted by a hydrolysis and condensation reaction under an action of an acid catalyst.

3. The display panel of claim 2, wherein the vinyl alkoxysilane is vinyl trimethoxy silane.

4. The display panel of claim 2, wherein the vinyl alkoxysilane is vinyl trichloro silane.

5. The display panel of claim 1, wherein via a polymerization reaction, the vinyl groups of the cage polysilsesquioxanec are connected to a skeleton of the acrylate polymerskeleton.

6. The display panel of claim 5, wherein the polymerization reaction is a free radical polymerization.

7. The display panel of claim 5, wherein the polymerization reaction is an emulsion polymerization.

8. The display panel of claim 5, wherein the acrylate polymer is one or a group selected from methacrylate, ethyl acrylate, epoxy acrylate, and pure acrylate.

9. A display panel, wherein a photoresist layer of the display panel comprises a negative photoresist material, the negative photoresist material comprises an acrylate polymer with cage polysilsesquioxanec.

10. The display panel of claim 9, wherein functional groups connected to Si atoms located at eight corners of a cage structure of the cage polysilsesquioxanec are vinyl groups.

11. A negative photoresist material, wherein the negative photoresist material comprises an acrylate polymer with cage polysilsesquioxanec.

12. The negative photoresist material of claim 11, wherein functional groups connected to Si atoms located at eight corners of a cage structure of the cage polysilsesquioxanec are vinyl groups.

13. The negative photoresist material of claim 12, wherein the vinyl groups of the cage polysilsesquioxanec are connected to a skeleton of the acrylate polymerskeleton.

14. The negative photoresist material of claim 13, wherein the cage polysilsesquioxanec is obtained by vinyl alkoxysilane reacted by a hydrolysis and condensation reaction under an action of an acid catalyst.

15. The negative photoresist material of claim 14, wherein the vinyl alkoxysilane is vinyl trichloro silane.

16. The negative photoresist material of claim 14, wherein the vinyl alkoxysilane is vinyl trichloro silane.

17. The negative photoresist material of claim 13, wherein via a polymerization reaction, the vinyl groups of the cage polysilsesquioxanec are connected to the acrylate polymerskeleton.

18. The negative photoresist material of claim 17, wherein the polymerization reaction is a free radical polymerization.

19. The negative photoresist material of claim 17, wherein the polymerization reaction is an emulsion polymerization.

20. The negative photoresist material of claim 17, wherein the acrylate polymer is one or a group selected from methacrylate, ethyl acrylate, epoxy acrylate, and pure acrylate.
